(19) United States
(12) Patent Application Publication
(10) Pub. No.: US 2025/0096448 A1
(43) Pub. Date: Mar. 20, 2025

(54) CERAMIC PACKAGE HIGH BANDWIDTH RF FEEDTHROUGH

(71) Applicant: Infinera Corporation, San Jose, CA (US)

(72) Inventor: Jiaming Zhang, Macungie, PA (US)

(73) Assignee: Infinera Corporation, San Jose, CA (US)

(21) Appl. No.: 18/368,475

(22) Filed: Sep. 14, 2023

(51) Int. Cl. H01P 3/02; H01L 23/053; H01L 23/498; H01P 3/00; H01P 3/08

(52) U.S. Cl. CPC H01P 3/026; H01L 23/49838; H01P 3/003; H01P 3/08; H01L 23/053

(57) ABSTRACT

Consistent with an aspect of the present disclosure, a package is provided that has a wall, the wall having a first surface and a second surface opposite the first surface. A plurality of conductors is also provided. First portions of each of the plurality of conductors extend in a direction away from the first surface, the first portions of each of the plurality of conductor constituting a first waveguide having a first waveguide structure. In addition, second portions of each of the plurality of conductors are embedded in the wall, the second portions of each of the plurality of conductors constituting a second waveguide having a second waveguide structure. Further, third portions of each of the plurality of conductors constitute a third waveguide having the first waveguide structure. It is to be understood that both the foregoing general description and the following detailed description are exemplary and explanatory only and are not restrictive of the invention, as claimed.

### BACKGROUND

In optical communication systems, optical signals are transmitted from a transmitter to a receiver. Each optical signal can carry a respective data stream and have an associated frequency or wavelength. In order to increase the data-carrying capacity of an optical communication system, the optical signal frequencies may be spectrally spaced close to one another. In addition, the data or symbol rate associated with each optical signal may be increased.

Optical modules are often implemented in optical communication systems. Such modules may contain an optical transmitter and an optical receiver. The optical transmitter may include driver circuitry for driving one or more Mach-Zehnder modulators, as well as digital signal processor and digital to analog converter (DAC) that provides analog signals that are input to the driver circuitry. Certain electrical connections between the DACs and the driver circuitry may be realized with transmission lines that support high frequency transmission. Selected transmission lines extend through a wall of a package housing the modulators and driver circuitry, as well as photodiodes and transimpedance amplifiers, if the transmit and receiver portions are commonly housed in the same transceiver package.

At high frequencies in excess of 80 GHz associated with baud rates of 96-100 Gbaud/s and 800 Gbit/s transmission, conventional transmission lines or waveguides may support higher order modes that draw energy from the fundamental mode. As a result, the fundamental transverse electromagnetic (TEM) mode loses energy (“suck out”) that decreases the signal to noise rate of the transmitted signal and reduces radio frequency bandwidth.

### SUMMARY

Consistent with an aspect of the present disclosure, a package is provided that has a wall, the wall having a first surface and a second surface opposite the first surface. A plurality of conductors is also provided. First portions of each of the plurality of conductors extend in a direction away from the first surface, the first portions of each of the plurality of conductor constituting a first waveguide having a first waveguide structure. In addition, second portions of each of the plurality of conductors are embedded in the wall, the second portions of each of the plurality of conductors constituting a second waveguide having a second waveguide structure. Further, third portions of each of the plurality of conductors constitute a third waveguide having the first waveguide structure. It is to be understood that both the foregoing general description and the following detailed description are exemplary and explanatory only and are not restrictive of the invention, as claimed.

The accompanying drawings, which are incorporated in and constitute a part of this specification, illustrate one (several) embodiment(s) and together with the description, serve to explain the principles of the invention.

### BRIEF DESCRIPTION OF THE DRAWINGS

FIG. 1 illustrates a transmitter portion of a transmitter receiver optical sub-assembly (TROSA) consistent with an aspect of the present disclosure;

FIG. 2 illustrates a receiver portion of the TROSA consistent with an additional aspect of the present disclosure;

FIG. 3 shows a perspective view of a package consistent with an aspect of the present disclosure;

FIG. 4 shows a cross-sectional view of the package shown in FIG. 3;

FIGS. 5a and 5b show cross-sectional views of waveguides consistent with an aspect of the present disclosure;

FIGS. 6a and 6b show plots of insertion loss associated with the waveguides shown in FIGS. 5a and 5b, respectively; various characteristics of the low pass filter consistent with the present disclosure; and

FIG. 7 shows a plan view of a plurality of waveguides consistent with a further aspect of the present disclosure; and

FIG. 8 shows an alternative plan view of a plurality of waveguides consistent with an additional aspect of the present disclosure.

### DESCRIPTION OF THE EMBODIMENTS

Consistent with the present disclosure, a combination of different waveguides is provided that increases the frequency at which “suck out” occurs. In one example, differential transmission is supported by pairs of conductors or traces. Such traces are provided in a surface differential coplanar waveguide structure outside the package. Inside the package wall or embedded in the wall, the traces are provided in a pair of buried single-ended coplanar waveguide structures, and, within the package, the traces are provided in another surface differential coplanar waveguide structure. Such waveguide structures have geometries and dielectrics that increase the frequency at which higher order modes are supported, such that energy “suck out” occurs at frequencies higher than that associated with high data rate transmission. In one example, the “suck out” related frequencies are greater than 85 GHZ, such that energy loss of the fundamental mode at frequencies of 85 GHz is reduced. As a result, improved transmission with fewer errors and an increased signal-to-noise ratio can be realized.

Reference will now be made in detail to the present exemplary embodiments of the present disclosure, which are illustrated in the accompanying drawings. Wherever possible, the same reference numbers will be used throughout the drawings to refer to the same or like parts.

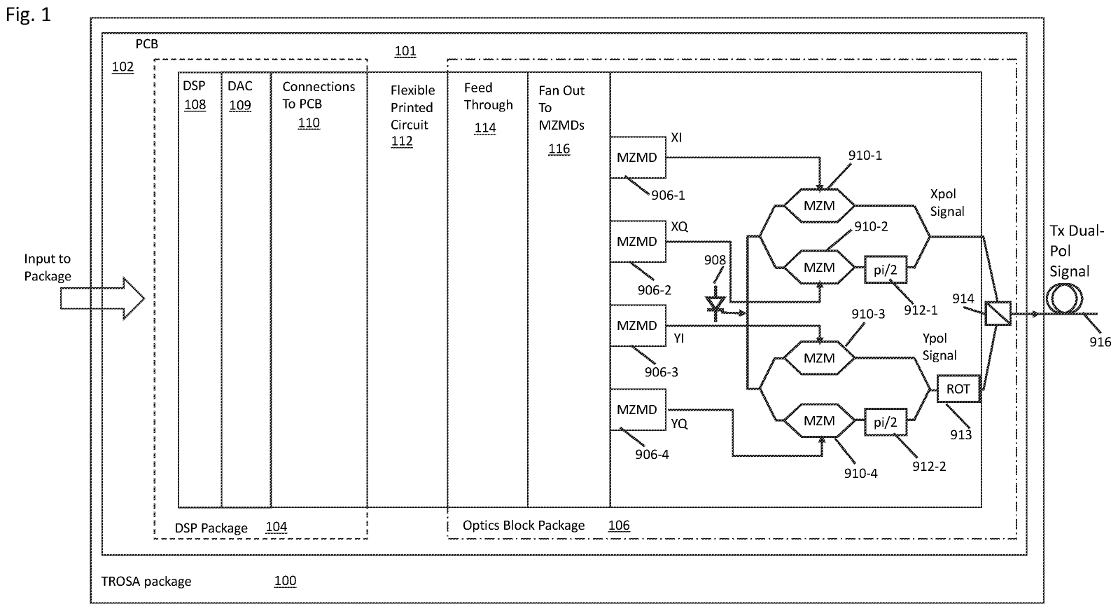

FIG. 1 illustrates a transmitter portion 101 included in a TROSA package 100. Transmitter portion 101 includes a DSP package 104 and an optics block package 106, both of which are provided on a printed circuit board (PCB) 102. DSP package 104 includes a digital signal processor (DSP) 108 and DAC circuitry 109. The analog signals supplied by DAC circuitry 109 are transmitted over electrical paths including conductors in connections 110 to PCB 102, conductors in a flexible printed circuit 112, conductors in a feed through of package 106, and conductors of a fan out 116 that connect to Mach-Zehnder modulator driver circuits (MZMDs) 906-1 to 906-4.

In operation, data is input to TROSA package 100 and provided to DSP 108. The data is processed in DSP 108, which outputs digital signals to DAC 109. Based on the digital signals, DAC 109 provides analog signals to PCB connections 110. The analog signals next propagate to conductors in flexible printed circuit 112 and then to conductors in feed through 114 in a wall of package 106. Conductors in fan out 116 receive the analog signals from the feed through conductors or traces 114 and supply the analog signal to MZMDs 906-1 to 906-4. Each MZMD in turn generates modulator drive signals for driving a respective one of modulators 910-1 to 910-4.

Each of the modulators 910-1 to 910-4 may be a Mach-Zehnder modulator (MZM) that modulates the phase and/or amplitude of the light output from laser 908. As further shown in FIG. 1, a light beam output from laser 908 (also included in package 106) is split such that a first portion of the light is supplied to a first MZM pairing including MZMs 910-1 and 910-2 and a second portion of the light is supplied to a second MZM pairing including MZMs 910-3 and 910-4.

The first portion of the light is further split into third and fourth portions, such that the third portion is modulated by MZM 910-1 to provide an in-phase (I) component of an X (or TE) polarization component of a modulated optical signal, and the fourth portion is modulated by MZM 910-2 and fed to phase shifter 912-1 to shift the phase of such light by 90 degrees in order to provide a quadrature (Q) component of the X polarization component of the modulated optical signal.

Similarly, the second portion of the light is further split into fifth and sixth portions, such that the fifth portion is modulated by MZM 910-3 to provide an I component of a Y (or TM) polarization component of the modulated optical signal, and the sixth portion is modulated by MZM 910-4 and fed to phase shifter 912-2 to shift the phase of such light by 90 degrees to provide a Q component of the Y polarization component of the modulated optical signal.

The optical outputs of MZMs 910-1 and 910-2 are combined to provide an X polarized optical signal including I and Q components and fed to a polarization beam combiner (PBC) 914 provided in block 901. In addition, the outputs of MZMs 910-3 and 910-4 are combined to provide an optical signal that is fed to polarization rotator 913, further provided in block 901, that rotates the polarization of such optical signal to provide a modulated optical signal having a Y (or TM) polarization. The Y polarized modulated optical signal is also provided to PBC 914, which combines the X and Y polarized modulated optical signals to provide a polarization multiplexed (“dual-pol”) modulated optical signal onto optical fiber 916, which extends from package 106 outside of TROSA package 100.

In some implementations, the polarization multiplexed optical signal output from package 100 includes optical subcarriers. Namely, such optical subcarriers are generated by modulating light output from a laser 908. In one example, each of optical subcarriers is a Nyquist subcarrier. Nyquist subcarriers is a group of optical signals, each carrying data, wherein (i) the spectrum of each such optical signal within the group is sufficiently non-overlapping such that the optical signals remain distinguishable from each other in the frequency domain, and (ii) such group of optical signals is generated by modulation of light from a single laser. In general, each subcarrier may have an optical spectral bandwidth that is at least equal to the Nyquist frequency, as determined by the baud rate of such subcarrier.

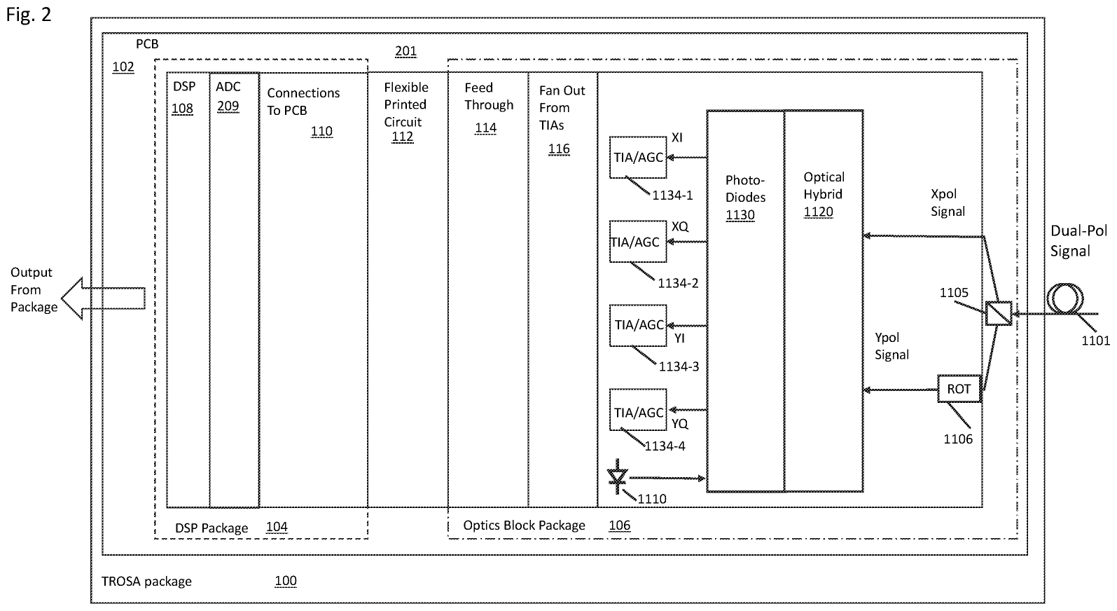

The receive portion of TROSA package 100 will next be described with reference to FIG. 2. Collectively, the transmit and receiver portions constitute a transceiver provided in package 100.

As shown in FIG. 2, receiver portion 201 includes portions of circuitry included in DSP package 104 and optics block package 106. Namely, optics block package 106 includes a polarization splitter 1105 with first and second outputs, a local oscillator (LO) laser 1110, 90 degree optical hybrid circuitry or mixer circuitry 1120, detectors or photodiode circuitry 1130 including individual photodiodes or photodiode pairs, such as balanced photodiode, and AC coupling capacitors (not shown).

In one example, one laser may be provided that is “shared” between the transmitter and receiver portions. In that case, laser 1110 may be omitted.

As further shown in FIG. 2, trans-impedance amplifiers/automatic gain control circuits 1134 (“TIA/AGC 1134”) are provided that provide analog signals over conductors including in fan tout 116, feed through 114 in a wall of package 106, flexible circuit 112, and PCB connections to analog-to-digital conversion circuitry 209.

Polarization beam splitter (PBS) 1105 may include a polarization splitter that receives an input polarization multiplexed optical signal including optical subcarriers by optical fiber link 1101. PBS 1105 may split the incoming optical signal into the two X and Y orthogonal polarization components. The Y component may be supplied to a polarization rotator 1106 that rotates the polarization of the Y component to have the X polarization. Optical hybrids 1120 may combine the X and rotated Y polarization components with light from local oscillator laser 1110. For example, optical hybrid circuits may combine a first polarization signal (e.g., the component of the incoming optical signal having a first or X (TE) polarization output from a first port of PBS 1105) with light from local oscillator laser 1110, and combine the rotated polarization signal (e.g., the component of the incoming optical signal having a second or Y (TM) polarization output from a second port of PBS 1105) with the light from local oscillator laser 1110.

Photodiode circuitry 1130 may detect mixing products output from the optical hybrid circuitry 1120, to form corresponding voltage signals, which are subject to AC coupling by capacitors, as well as amplification and gain control by TIA/AGCs 1134-1 to 1134-4. In some implementations, the TIA/AGCs 1134 are used to smooth out or correct variations in the electrical signals output from detector 1130 and the AC coupling capacitors.

As further shown in FIG. 2, the analog signals supplied by TIA/AGCs 1134-1 to 1134-4 are supplied to ADC circuitry 209 by way of conductors included in fan out 116, feed through 114, flexible printed circuit 112, and PCB connections 110. ADC circuitry 209 receives the analog signals and converts the analog signals to digital samples or digital signals, which are then supplied to DSP 108. Based on the received digital signals from ADC 209, DSP 108 outputs the client data from package 104. The output client data is then supplied or output from package 100.

While FIGS. 1 and 2 show TROSA package 100 as including a particular quantity and arrangement of components, in some implementations, TROSA package 100 may include additional components, fewer components, different components, or differently arranged components. In some instances, one of the components illustrated in FIGS. 1 and 2 may carry out a function described herein as being carry outed by another one of the components illustrated in FIGS. 1 and 2.

Consistent with the present disclosure, in order to demodulate the subcarriers 8, local oscillator laser 1110 may be tuned to output light having a wavelength or frequency relatively close to one or more of the subcarrier wavelengths or frequencies to thereby cause a beating between the local oscillator light and the subcarriers.

In one example, the local oscillator laser may be a semiconductor laser, which may be tuned thermally or through current adjustment. If thermally tuned, the temperature of the local oscillator laser 1110 is controlled with a thin film heater, for example, provided adjacent the local oscillator laser. Alternatively, the current supplied to the laser may be controlled, if the local oscillator laser is current tuned. The local oscillator laser 1110 may be a semiconductor laser, such as a distributed feedback laser or a distributed Bragg reflector laser.

Selected traces or conductors, such as those described below may carry analog signals in a first direction to MZMDs 906 as part of transmit portion 101, and other traces or conductors may carry analog signals in a second direction to ADC circuitry 209 as part of receiver portion 201.

In FIGS. 1 and 2, portions of DSP 108 may be used as part of the transmitter portion 101 to generate modulated optical signals and other portions of DSP 108 may be used as part of receiver portion 201 to process data associated with received optical signals.

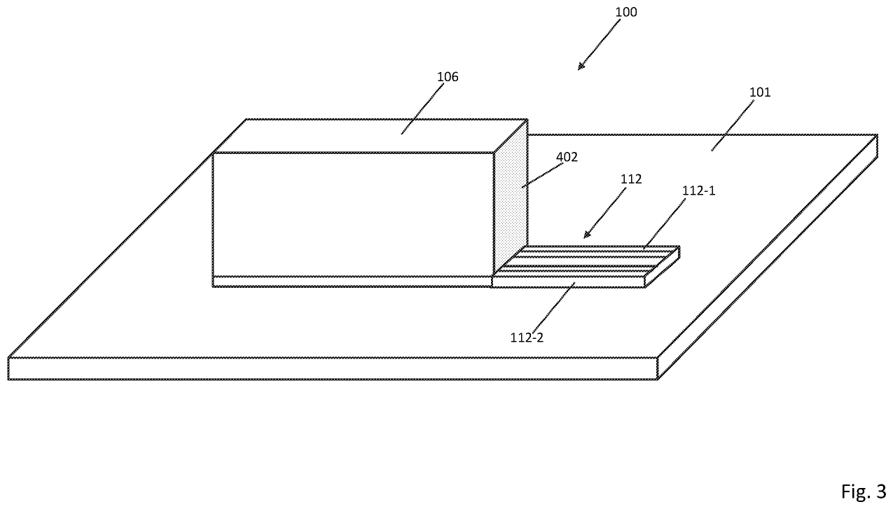

FIG. 3 shows a simplified perspective view of package 106 on printed circuit board 102. As shown in FIG. 3, traces or conductors 112-1 are provided on an insulator or insulative substrate 112-2, and, collectively, the conductors and insulator constitute, in one example, flexible printed circuit 112. As described in further detail below, the conductors 112-1 may be provided as part of a surface differential coplanar waveguide structure. In another example, insulator 112-2 may include a ceramic.

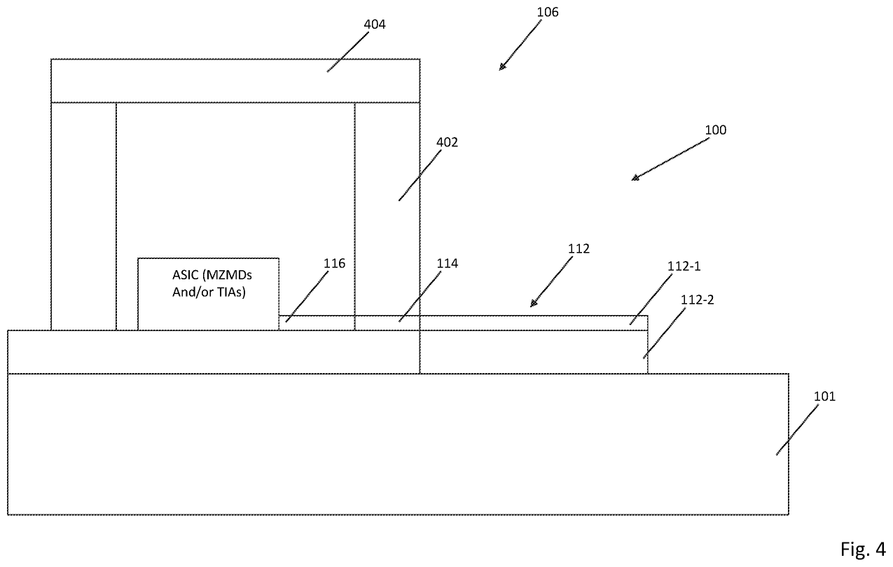

FIG. 4 shows a cross-sectional view of a portion of package 100 including package 106 provided on printed circuit board 101. As noted above, a flexible printed circuit, in one example, provides analog signals to or from circuitry, such as an application specific integrated circuits (ASICs) included in package 106. Traces provided on insulator or insulative substrate 112-2 have a first portion 112-1 that extends to a second portion of the traces that constitute part of feed through 114 embedded in or otherwise included in wall 402. The traces have a third portion included in fanout 116 that connect with an ASIC or ASICs in package 106. Wall 402, in one example, includes a ceramic material.

The first portion of each of the traces is preferably included in a surface differential coplanar waveguide structure, and the second portion of each of the traces is preferably included in a buried single ended coplanar waveguide structure. Moreover the third portion of each of the traces is preferably included in a surface differential coplanar waveguide structure.

As further shown in FIG. 4, a lid 404 may be provided on walls 402, and, in one example, the walls 402 and lid hermetically seal package 106. Optical components, such as laser 90-8, MZMs 910 rotator 913, polarization beam combiner 914, splitter 1105, rotator 1106, optical hybrids 1120, and photodiodes 1130 are not shown in FIG. 4 for ease of illustration.

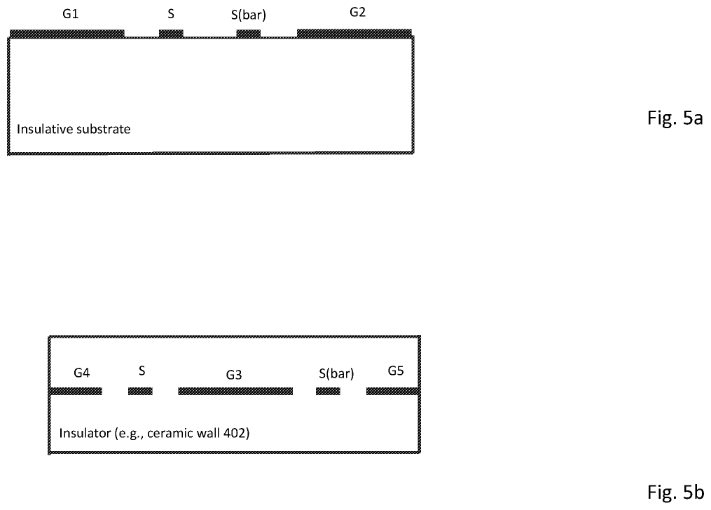

FIG. 5a shows an example, of a cross-sectional view of surface differential coplanar waveguide structure, which include first and second signal conductors carrying a signal(S) and the inverse of the signal (Sbar), which is spaced from the conductor carrying signal S. Ground conductors (G1 and G2) are provided adjacent the signal and signal-bar conductors, respectively, but not in between. The ground, S, and Sbar conductors are provided on an insulating material or dielectric (I), which may include a ceramic or an organic material, such as polyimide or a resin, as part of a flexible circuit. Here, the relative low dielectric constant of air above the signal and signal bar conductors causes the energy “suck out” frequency, i.e., the frequency at which higher order modes are supported and draw energy from the fundamental mode, to increase. As noted above, the surface differential coplanar waveguide structure may be provided outside package 106, as well as inside package 106, to connect to conductor sections or portions embedded in the wall 402 of package 106.

FIG. 5b shows an example of a cross-sectional view of a pair of buried single-ended coplanar waveguide structures, which include first and second signal conductors carrying signal(S) and the inverse of the signal (Sbar). Ground conductors G3 and G4 are provided adjacent signal conductors S and Sbar. In addition, a third ground conductor, G5, is provided between the S and Sbar conductors. Here, the dielectric selected and geometry of the ground, S, and Sbar electrodes are such that the “suck out” frequency is increased beyond that of the frequencies associated with data or signal transmission, as noted above. In addition, as further noted above, conductor or trace portions within wall 402 have the single-ended coplanar waveguide structure.

It is noted that in order to facilitate differential transmission, two single ended coplanar waveguide conductors are provided, one carrying S signals and the other carrying the inverse (Sbar) signals, with a shared ground conductor in between. An individual single ended coplanar waveguide includes a single trace or conductor carrying a signal with a ground conductor provided on opposite sides of such signal carrying conductor. Accordingly, ground conductor G5 is provided between the S and S (bar) carrying conductors, as shown in FIG. 5b, such that both the signal(S) and S (bar) conductors are provided between ground conductors.

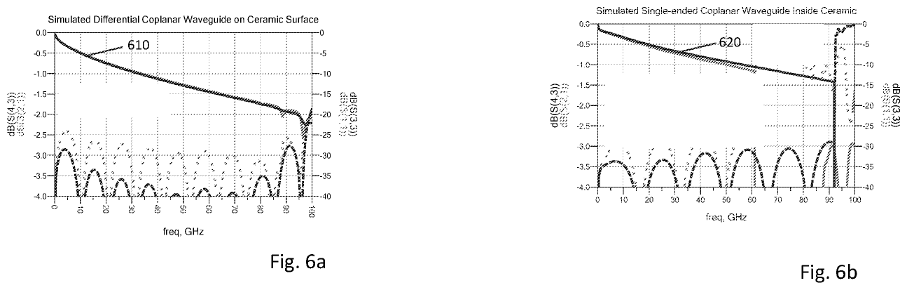

FIG. 6a shows an example of insertion loss (dB) as a function of signal frequency associated with transmission through surface differential coplanar waveguide structure, such as that shown in FIG. 5a, for example. In particular, plot 610 has relatively low loss up to a signal frequency of about 90 GHz, which, as noted above, facilitates high speed data transmission of 800 Gbit/s and associated signal frequencies at frequencies of 85 GHz. Such frequencies are associated with baud rates of 96-100 Gbaud/s as noted above. In another example, the waveguides have an associated cut-off frequency of 85 GHZ. In a further example, the cut-off frequency is greater than 85 GHz.

FIG. 6b shows an example of insertion loss (dB) as a function of signal frequency associated with transmission through a single-ended coplanar waveguide structure, such as that shown in FIG. 5b. In particular, plot 620, similar to plot 620, has relatively low loss up to a signal frequency of about 90 GHZ, and, therefore, also support 800 Gbit/s transmission.

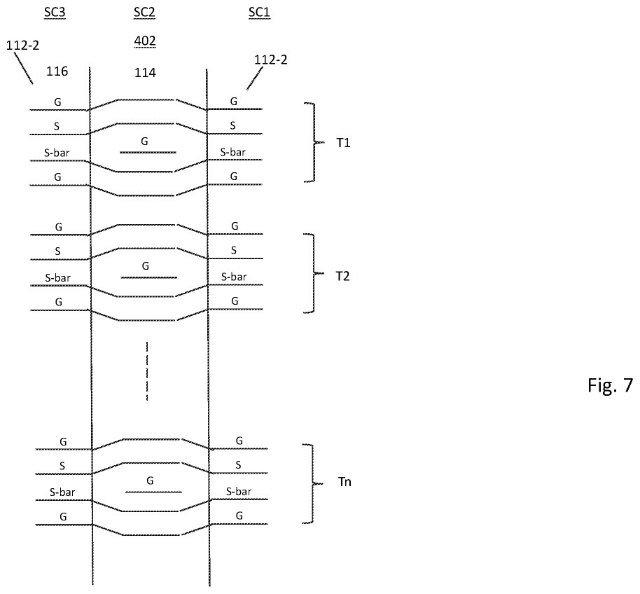

FIG. 7 shows an example of a plan view of a plurality of waveguide trace groupings T1 to Tn consistent with the present disclosure. Each trace grouping includes a first section SC1, a second section SC2, and a third section SC3. The first section, includes conductors or traces arranged in the surface differential coplanar waveguide configuration on insulator 112-2 outside of package 106. As noted above, the traces are configured as ground (G)-signal(S)-signal (bar) (S (bar))-ground (G).

Section SC2 of each trace grouping T1 to Tn includes traces arranged as two single-coplanar waveguides including signals S and its inverse S (bar) on respective traces. As further shown in FIG. 7, such waveguides are embedded or buried in wall 402 as fanout section or portion 114. Accordingly, the traces of each trace grouping T1 to Tn in Section SC2 are configured as ground (G)-signal(S)-ground (G)-signal S (bar) (S (bar))-ground (G).

In addition, the traces of each trace grouping T1 to Tn in section SC3, within package 106, are arranged in the surface differential coplanar waveguide configuration. Namely, the traces are configured as ground (G)-signal(S)-signal (bar) (S (bar))-ground (G).

In one example, each trace in each trace grouping T1 to Tn extends continuously through sections SC1, SC2, and SC3, as shown in FIG. 7. As noted above, the traces in section SC3 connect to an ASIC in package 106, which, in one example, includes a modulator driver circuit and/or a transimpedance amplifier circuit.

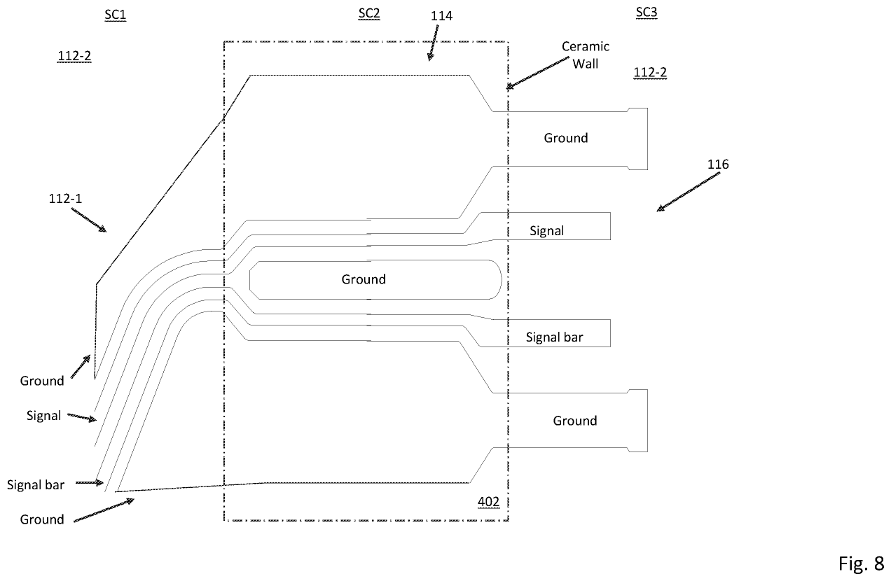

FIG. 8 shows another a plan view of waveguide trace grouping, wherein an example of a fanout 114 is shown in greater detail. It is noted that the spacing of electrical connections to the DACs 109 and ADCs 209 may be different than the spacing between electrical connections to the ASIC including the drivers 906 and/or transimpedance amplifiers (TIAs) 1134. Accordingly, a width of ground conductors adjacent the signal and signal (bar) carrying electrodes, and the signal and signal (bar) carrying traces have angled portions A1 and A2 such that a spacing between the signal and signal (bar) electrodes in section SC2 is aligned with corresponding portions of the signal and signal (bar) electrodes in sections SC1 and SC3 to facilitate connections to the DACs 109/ADCs 209 and drivers 906/TIAs 1134.

Thus, by providing surface differential coplanar waveguides portions outside and within package 106, as well as buried single-ended coplanar waveguides within wall 402 of package 106, reduced insertion loss can be achieved over a range of signal frequencies and baud rates that facilitate high speed data transmission, for example, at 800 Gbit/s.

Other embodiments will be apparent to those skilled in the art from consideration of the specification. It is intended that the specification and examples be considered as exemplary only, with a true scope and spirit of the invention being indicated by the following claims.

What is claimed is:

1. An apparatus, comprising:
a package having a wall, the wall having a first surface and a second surface opposite the first surface; and
a plurality of conductors, first portions of each of the plurality of conductors extending in direction away from the first surface, the first portions of each of the plurality of conductor constituting a first waveguide having a first waveguide structure, second portions of each of the plurality of conductors being embedded in the wall, the second portions of each of the plurality of conductors constituting a second waveguide having a second waveguide structure, and third portions of each of the plurality of conductors constituting a third waveguide having the first waveguide structure.

2. An apparatus in accordance with claim 1, wherein the first waveguide structure is a surface differential coplanar waveguide structure.

3. An apparatus in accordance with claim 1, wherein the second waveguide structure is a buried single-ended coplanar waveguide structure.

4. An apparatus in accordance with claim 1, wherein the first waveguide structure is a surface differential coplanar waveguide structure and the second waveguide structure is a buried single-ended waveguide structure.

5. An apparatus in accordance with claim 1, wherein the package includes a ceramic material.

6. An apparatus in accordance with claim 1, wherein the second waveguide has an associated cut-off frequency that is greater than 85 GHz.

7. An apparatus in accordance with claim 1, wherein the plurality of conductors is provided on a substrate.
